(19) United States
(12) Patent Application Publication
(10) Pub. No.: US 2026/0135566 A1
(43) Pub. Date: May 14, 2026

(54) HYBRID TOP-BOTTOM PLATE SAMPLING SCHEME IN SUCCESSIVE APPROXIMATION REGISTER (SAR) ANALOG-TO-DIGITAL CONVERTER (ADC) FOR CHARGE INJECTION REDUCTION

(71) Applicant: QUALCOMM Incorporated, San Diego, CA (US)

(72) Inventors: Ramkumar SIVAKUMAR, San Diego, CA (US); Chienchung YANG, San Diego, CA (US)

(21) Appl. No.: 18/948,238

(22) Filed: Nov. 14, 2024

(51) Int. Cl. H03M 1/46; H03M 1/36

(52) U.S. Cl. CPC H03M 1/462; H03M 1/368; H03M 1/466

(57) ABSTRACT

A method for operating an analog-to-digital converter (ADC) is provided. The ADC includes a comparator, a sampling switch coupled between a device outputting an analog voltage and an input of the comparator, and a capacitor array including capacitors, wherein top plates of the capacitors are coupled between the sampling switch and the input of the comparator. The method includes, during a first phase, closing the sampling switch and coupling bottom plates of the capacitors to a common mode voltage, during a second phase, decoupling the bottom plates of the capacitors from the common mode voltage while the sampling switch is closed, during a third phase, opening the sampling switch while the bottom plates of the capacitors are decoupled from the common mode voltage, and, during a fourth phase, coupling the bottom plates of capacitors to the common mode voltage while the sampling switch is open.

### BACKGROUND

### Field

Aspects of the present disclosure relate generally to analog-to-digital converters (ADCs)) and more particularly to successive approximation register (SAR) ADCs.

### Background

An analog-to-digital converter (ADC) is used to convert an analog signal into a digital signal. One type of ADC is the successive approximation register (SAR) ADC, which converts an analog input signal into a digital signal using successive approximation based on a binary search. SAR ADCs have become popular for implementing low-power ADCs in advanced technologies.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to an analog-to-digital converter (ADC). The ADC includes a comparator, a first sampling switch coupled to a first input of the comparator, and a capacitive digital-to-analog convert (DAC). The capacitive DAC includes a first capacitor array including first capacitors, wherein top plates of the first capacitors are coupled between the first sampling switch and the first input of the comparator, and a first switching circuit configured to selectively couple bottom plates of the first capacitors to a common mode voltage. The ADC also includes a switch control circuit configured to, during a first phase, close the first sampling switch and cause the first switching circuit to couple the bottom plates of the first capacitors to the common mode voltage, during a second phase, cause the first switching circuit to decouple the bottom plates of the first capacitors from the common mode voltage while the first sampling switch is closed, during a third phase, open the first sampling switch while the bottom plates of the first capacitors are decoupled from the common mode voltage, and, during a fourth phase, cause the first switching circuit to couple the bottom plates of first capacitors to the common mode voltage while the first sampling switch is open. The ADC also includes a successive approximation register (SAR) coupled to an output of the comparator, wherein, during the fourth phase, the SAR is configured to make a bit decision based on the output of the comparator.

A second aspect relates to a method for operating an analog-to-digital converter (ADC). The ADC includes a comparator, a sampling switch coupled between a device outputting an analog voltage and an input of the comparator, and a capacitor array including capacitors, wherein top plates of the capacitors are coupled between the sampling switch and the input of the comparator. The method includes, during a first phase, closing the sampling switch and coupling bottom plates of the capacitors to a common mode voltage, during a second phase, decoupling the bottom plates of the capacitors from the common mode voltage while the sampling switch is closed, during a third phase, opening the sampling switch while the bottom plates of the capacitors are decoupled from the common mode voltage, and, during a fourth phase, coupling the bottom plates of capacitors to the common mode voltage while the sampling switch is open.

### BRIEF DESCRIPTION OF THE DRAWINGS

FIG. 1A shows an example of a system including an ADC and a device coupled to the ADC according to certain aspects of the present disclosure.

FIG. 1B shows an example of multiple devices coupled to the ADC through a multiplexer according to certain aspects of the present disclosure.

FIG. 2 shows an example of a SAR ADC using bottom plate sampling according to certain aspects of the present disclosure.

FIG. 3A shows an example of a switch configuration for the SAR ADC of FIG. 2 during a first phase according to certain aspects of the present disclosure.

FIG. 3B shows an example of a switch configuration for the SAR ADC of FIG. 2 during a second phase according to certain aspects of the present disclosure.

FIG. 3C shows an example of a switch configuration for the SAR ADC of FIG. 2 during a third phase according to certain aspects of the present disclosure.

FIG. 3D shows an example of a switch configuration for the SAR ADC of FIG. 2 during a fourth phase according to certain aspects of the present disclosure.

FIG. 4 shows an example of a SAR ADC using top plate sampling according to certain aspects of the present disclosure.

FIG. 5A shows an example of a switch configuration for the SAR ADC of FIG. 4 during a first phase according to certain aspects of the present disclosure.

FIG. 5B shows an example of a switch configuration for the SAR ADC of FIG. 4 during a second phase according to certain aspects of the present disclosure.

FIG. 6 shows an example of switches for the SAR ADC of FIG. 4 implemented with bootstrap switches according to certain aspects of the present disclosure.

FIG. 7 illustrates charge injection into the SAR ADC of FIG. 4 when a switch is opened according to certain aspects of the present disclosure.

FIG. 8A shows another example of a switch configuration for the SAR ADC of FIG. 4 during a first phase according to certain aspects of the present disclosure.

FIG. 8B shows another example of a switch configuration for the SAR ADC of FIG. 4 during a second phase according to certain aspects of the present disclosure.

FIG. 8C shows an example of a switch configuration for the SAR ADC of FIG. 4 during a third phase according to certain aspects of the present disclosure.

FIG. 8D shows an example of a switch configuration for the SAR ADC of FIG. 4 during a fourth phase according to certain aspects of the present disclosure

FIG. 9 illustrates charge injection reduction in the SAR ADC of FIG. 4 according to certain aspects of the present disclosure.

FIG. 10 is a flowchart illustrating a method for operating an ADC according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However it will be apparent to those skilled in the art that these concepts may be practiced without these specific details. In some instances well-known structures and components are shown in block diagram form in order to avoid obscuring such concepts.

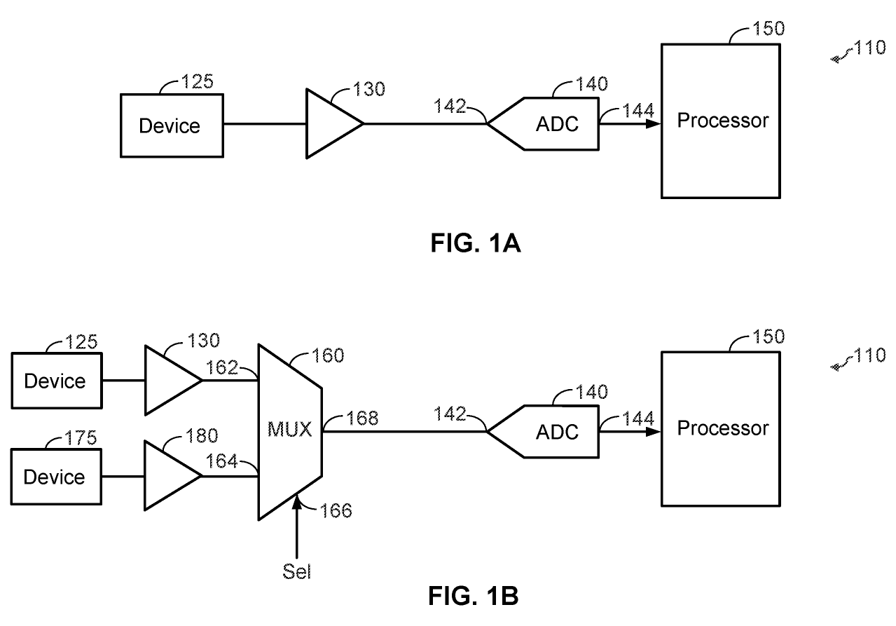

An ADC may be used in a system to convert an analog signal into a digital signal. In this regard, FIG. 1A shows an example of a system 110 in which an ADC 140 may be used according to certain aspects. The system 110 also includes a device 125, a driver 130 (e.g., an amplifier) coupled between the device 125 and the input 142 of the ADC 140, and a processor 150 coupled to the output 144 of the ADC 140. The input 142 of the ADC 140 may be a single-ended input or a differential input. The device 125 may include a peripheral device, a sensor device, or another type of device. The processor 150 may include a processor core, a digital signal processor (DSP), an application specific integrated circuit (ASIC), a field programmable gate array (FPGA) or other programmable logic device, or any combination thereof.

In this example, the driver 130 (e.g., an amplifier) is configured to receive an analog signal from the device 125 and drive the input 142 of the ADC 140 with the analog signal. The ADC 140 is configured to sample the analog signal (e.g., analog voltage) at the input 142, convert the sampled analog signal into a digital signal, and output the digital signal at the output 144. The processor 150 may then process the digital signal. For example, the device 125 may include a temperature sensor for monitoring temperature on a chip or another environment. In this example, the digital signal provides a digital temperature reading, which may be used by the processor to monitor the temperature. In other examples, the device 125 may include a voltage sensor, a current sensor, or another type of sensor device.

It is to be appreciated that the ADC 140 is not limited to a single device and that the ADC 140 may be used to convert analog signals from multiple devices into digital signals. In this regard, FIG. 1B shows an example in which the ADC 140 is used to convert analog signals from multiple devices into digital signals. In the example shown in FIG. 1B, the multiple devices include the device 125 discussed above and a second device 175. In this example, the system 110 also includes a second driver 180 and a multiplexer 160 for switching the input 142 of the ADC 140 between the devices 125 and 175. In the discussion below, the device 125 is referred to as the first device and the driver 130 is referred to as the first driver.

In this example, the multiplexer 160 has a first input 162, a second input 164, a select input 166, and an output 168. The first driver 130 is coupled between the first device 125 and the first input 162 of the multiplexer 160, the second driver 180 is coupled between the second device 175 and the second input 164 of the multiplexer 160, and the output 168 of the multiplexer 160 is coupled to the input 142 of the ADC 140. The multiplexer 160 is configured to receive a select signal at the select input 166, select the first input 162 or the second input 164 based on the select signal, and couple the selected input to the output 168.

In this example, the multiplexer 160 allows the ADC 140 to convert analog signals from the devices 125 and 175 into digital signals one at a time by switching the input 142 of the ADC 140 between the devices 125 and 175. When the multiplexer 160 selects the first input 162, the ADC 140 converts an analog signal from the first device 125 into a digital signal. When the multiplexer 160 selects the second input 164, the ADC 140 converts an analog signal from the second device 175 into a digital signal.

It is to be appreciated that the multiplexer 160 is not limited to two devices (i.e., the first device 125 and the second device 175) and that the multiplexer 160 may be used to selectively couple three of more devices to the input 142 of the ADC 140 one at a time. It is also to be appreciated that the first driver 130 and/or the second driver 180 may be omitted in some implementations.

The ADC 140 may be implemented with a successive approximation register (SAR) ADC. A SAR ADC converts an analog signal to a digital signal using successive approximation based on a binary search. The successive approximation may sequentially resolve the bit values of the digital signal starting with the most significant bit (MSB).

A SAR ADC may have a single-ended input or a differential input. A SAR ADC with a single-ended input converts a single-ended analog signal into a digital signal. For example, the single-ended analog signal may include an analog voltage Vin. In this example, the SAR ADC converts the analog voltage Vin into a digital signal. A SAR ADC with a differential input converts a differential analog signal into a digital signal. For example, the differential analog signal may include a first voltage VinP and a second voltage VinN. In this example, the SAR ADC converts the difference between the first voltage VinP and the second voltage VinN into a digital signal.

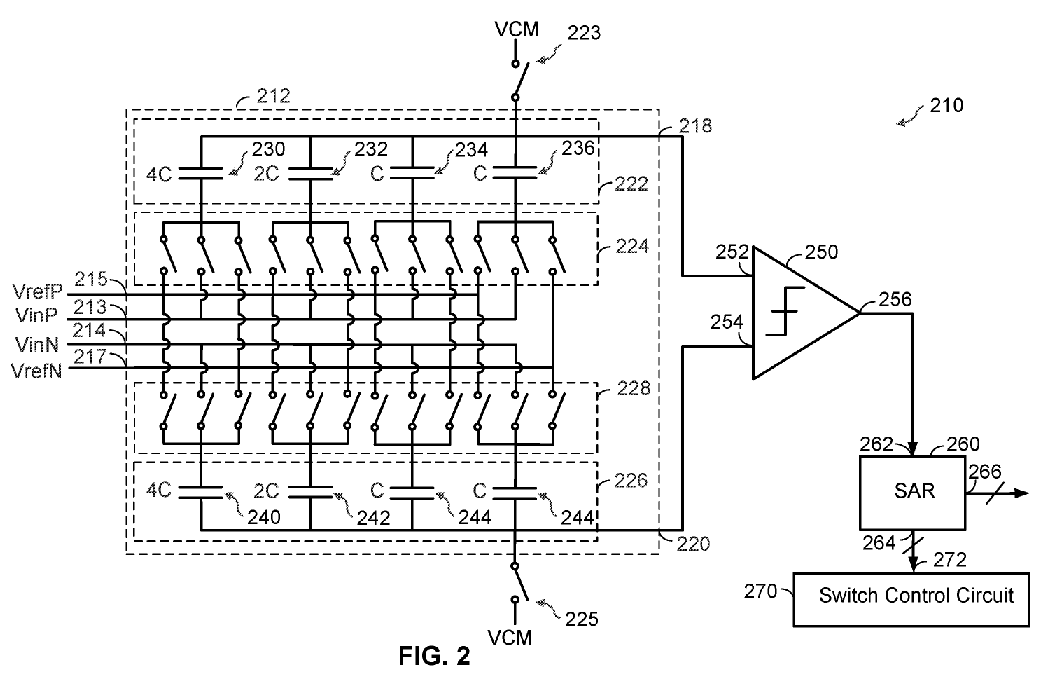

FIG. 2 shows an example of a differential SAR ADC 210 configured to convert a differential analog signal into a digital signal. The differential analog signal includes a first voltage VinP and a second voltage VinN. The SAR ADC 210 includes a capacitive DAC 212, a comparator 250, a SAR 260, a switch control circuit 270, a first switch 223, and a second switch 225. As discussed further below, the SAR ADC 210 uses bottom plate sampling to sample the differential analog signal.

The capacitive DAC 212 is configured to sample the first voltage VinP and the second voltage VinN. The capacitive DAC 212 is also used by the SAR 260 to resolve the bits of the digital signal based on the output of the comparator 250. The capacitive DAC 212 is discussed further below.

The comparator 250 has a first input 252, a second input 254, and an output 256. The first input 252 is coupled to a first output 218 of the capacitive DAC 212 and the second input 254 is coupled to a second output 220 of the DAC 212. The comparator 250 is configured to compare the voltage at the first input 252 with the voltage at the second input 254, and output a compare signal at the output 256 based on the comparison. In one example, the compare signal has a first logic value if the voltage at the first input 252 is greater than the voltage at the second input 254, and the compare signal has a second logic value if the voltage at the first input 252 is less than the voltage at the second input 254. The first logic value may be one and the second logic value may be zero, or vice versa.

In the example shown in FIG. 2, the capacitive DAC 212 includes a first capacitor array 222, a second capacitor array 226, a first switching circuit 224, and a second switching circuit 228. The first capacitor array 222 includes a set of capacitors 230, 232, 234, and 236. In this example, the capacitors 230, 232, and 234 are binary-weighted capacitors in which each of the capacitors 230, 232, and 234 corresponds to a respective bit of the digital signal and each of the capacitors 230, 232, and 234 has a capacitance equal to a unit capacitance C times a respective power of two. In the example shown in FIG. 2, the capacitor 234 has a capacitance of C, the capacitor 232 has a capacitance of 2C, and the capacitor 230 has a capacitance of 4C. In this example, the capacitor 230 corresponds to the most significant bit (MSB) of the digital signal. Although the first capacitor array 222 includes three binary-weighted capacitors corresponding to three bits in the example shown in FIG. 2, it is to be appreciated that the first capacitor array 222 may include a different number of binary-weighted capacitors corresponding to a different number of bits. In the example shown in FIG. 2, the capacitor 236 may be used as a dummy capacitor with a capacitance equal to one unit capacitance C. Each of the capacitors 230, 232, 234, and 236 has a respective top plate coupled to the first input 252 of the comparator 250 and a respective bottom plate coupled to the first switching circuit 224.

The second capacitor array 226 includes a set of capacitors 240, 242, 244, and 246, in which the capacitors 240, 242, and 244 are binary-weighted capacitors and the capacitor 246 is used as a dummy capacitor. In this example, the capacitor 244 has a capacitance of C, the capacitor 242 has a capacitance of 2C, and the capacitor 240 has a capacitance of 4C. Each of the capacitors 240, 242, 244, and 246 has a respective top plate coupled to the second input 254 of the comparator 250 and a respective bottom plate coupled to the second switching circuit 228.

In the example shown in FIG. 2, the capacitive DAC 212 receives the first voltage VinP at a first input 213, receives the second voltage VinN at a second input 214, receives a first reference voltage VrefP at a third input 215, and receives a second reference voltage VrefN at a fourth input 217. In this example, the first switching circuit 224 includes switches for selectively coupling the bottom plate of each of the capacitors 230, 232, 234, and 236 to VrefP, VinP, or VrefN. The second switching circuit 228 includes switches for selectively coupling the bottom plate of each of the capacitors 240, 242, 244, and 246 to VrefP, VinN, or VrefN.

The on/off states of the switches in the switching circuits 224 and 228 are controlled by the switch control circuit 270. For ease of illustration, the individual connections between the switches and the switch control circuit 270 are not shown in FIG. 2. The switch control circuit 270 has an input 272 coupled to the SAR 260. The switch control circuit 270 is configured to receive a digital signal from the SAR 260 at the input 272 and control the switches in the switching circuits 224 and 228 based on the digital signal, as discussed further below. As discussed further below, during a conversion phase, the SAR 260 sequentially changes the bits of the digital signal to test different bit values.

The switch control circuit 270 may also control the on/off state of the first switch 223 and the second switch 225. The first switch 223 is coupled between the top plates of the capacitors 230, 232, 234, and 236 and a common mode voltage VCM, and the second switch 225 is coupled between the top plates of the capacitors 240, 242, 244, and 246 and the common mode voltage VCM. The common mode voltage VCM is between the first reference voltage VrefP and the second reference voltage VrefN (e.g., VCM may be equal to an average of VrefP and VrefN).

The SAR 260 has an input 262, a first output 266, and a second output 264. The input 262 is coupled to the output 256 of the comparator 250 to receive the compare signal. The first output 266 is configured to output the digital signal representing the input differential analog signal (e.g., VinP-VinN) in the digital domain. The second output 264 is configured to output the digital signal to the switch control circuit 270 used to test different bit values during the conversion phase of the SAR ADC 210, as discussed further below.

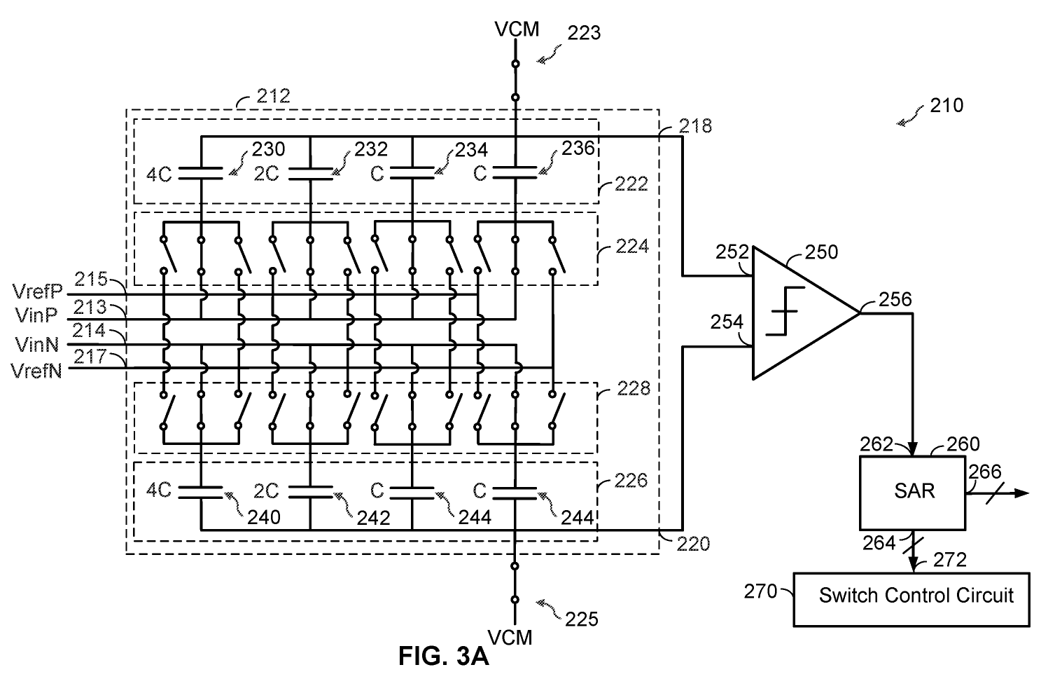

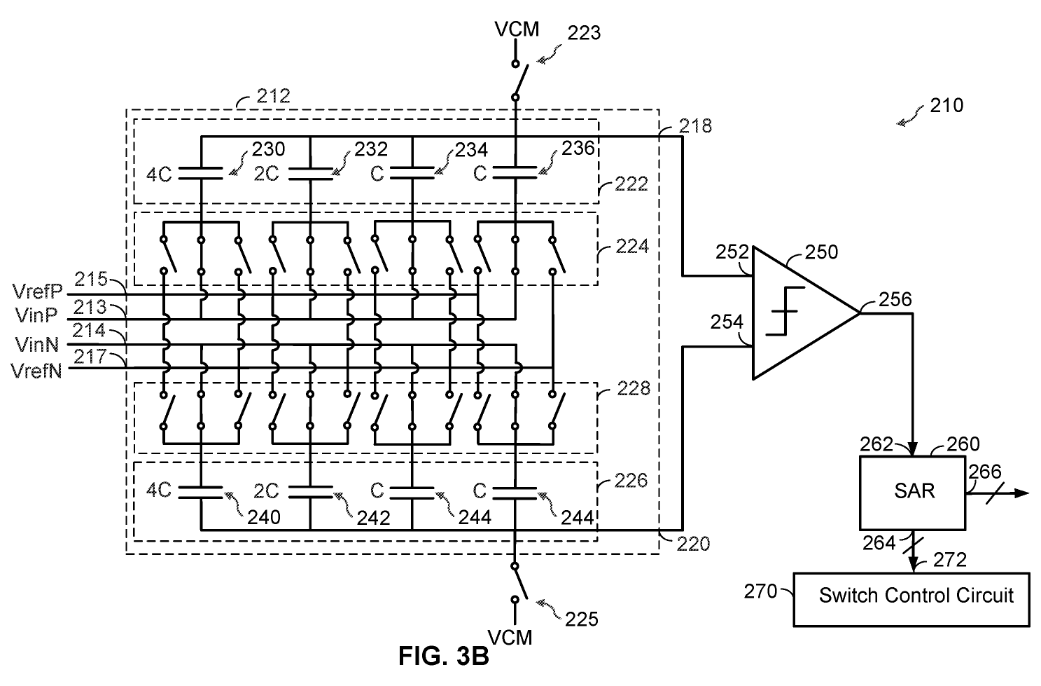

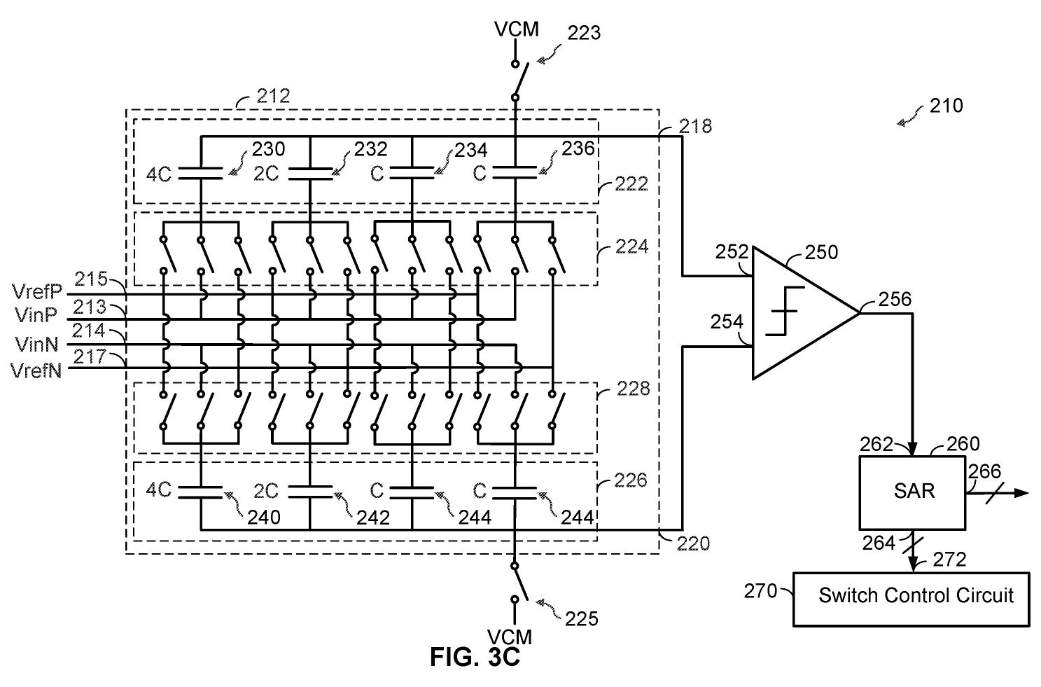

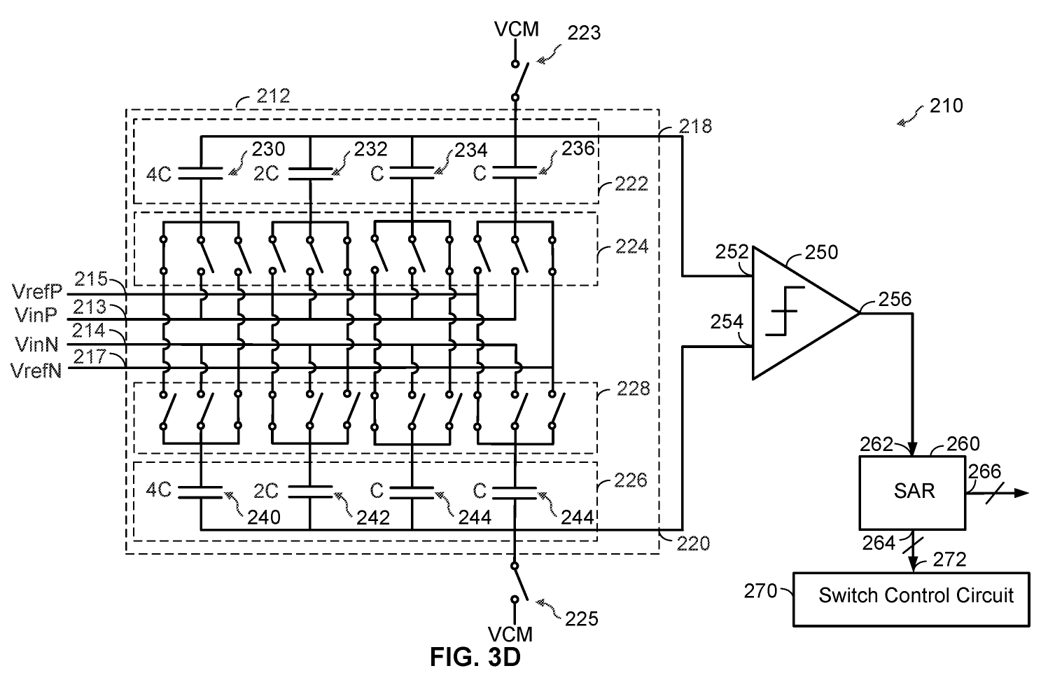

Exemplary operations of the SAR ADC 210 for converting the differential analog signal (which includes the voltages VinP and VinN) into the digital signal at the output 266 will now be described with reference to FIGS. 3A to 3D, which show the switch configurations of the switching circuits 224 and 228 and the switches 223 and 225 during different phases. As discussed above, the digital signal at the output 266 provides a digital representation of the voltage difference between the voltages VinP and VinN.

FIG. 3A shows an example of a first phase during which the voltages VinP and VinN of the differential analog signal are sampled. During the first phase, the switch control circuit 270 closes the switches 223 and 225, which couples the top plates of the capacitors 230, 232, 234, and 236 to the common mode voltage VCM and couples the top plates of the capacitors 240, 242, 244, and 246 to the common mode voltage VCM. The switch control circuit 270 also closes the switches between the bottom plates of the capacitors 230, 232, 234, and 236 and the first input 213 and closes the switches between the bottom plates of the capacitors 240, 242, 244, and 246 and the second input 214. As a result, the bottom plates of the capacitors 230, 232, 234, and 236 are coupled to the voltage VinP and the bottom plates of the capacitors 240, 242, 244, and 246 are coupled to the voltage VinN.

FIG. 3B shows an example of a second phase during which the switch control circuit 270 opens the switches 223 and 225 while leaving switches between the bottom plates of the capacitors 230, 232, 234, and 236 and the first input 213 closed and the switches between the bottom plates of the capacitors 240, 242, 244, and 246 and the second input 214 closed. During the second phase, the sample of the differential analog signal is taken. In this example, the capacitive DAC 212 samples the differential analog signal using bottom plate sampling in which the first voltage VinP is sampled at the bottom plates of the capacitors 230, 232, 234, and 236 and the second voltage VinN is sampled at the bottom plates of the capacitors 240, 242, 244, and 246.

FIG. 3C shows an example of a third phase during which the switch control circuit 270 opens the switches between the bottom plates of the capacitors 230, 232, 234, and 236 and the first input 213 and opens the switches between the bottom plates of the capacitors 240, 242, 244, and 246 and the second input 214 to hold the sampled differential analog signal.

FIG. 3D shows an example of a fourth phase during which the SAR ADC 210 tests the MSB to resolve the bit value of the MSB. The fourth phase may occur at the start of the conversion during which the SAR ADC 210 converts the sampled analog differential signal (e.g., voltage difference between sampled VinP and sampled VinN) into the digital signal at the output 266.

FIG. 3D shows the switch configuration of the switching circuits 224 and 228 for testing the bit value of the MSB. For example, the SAR 260 may output a digital signal of 100 to test the bit value of the MSB. In response, the switch control circuit 270 may switch the switches in the switching circuits 224 and 228 to the configuration shown in FIG. 3D. In this example, the MSB is initially set to one and the remaining bits are set to zero to test the bit value of the MSB.

After the switches in the switching circuits 224 and 228 are set to the configuration shown in FIG. 3D, the SAR 260 may resolve the bit value of the MSB based on the compare signal from the comparator 250. For example, if the compare signal has the second logic value (e.g., zero), then the SAR 260 may keep the MSB at the bit value of one. In this case, the switch control circuit 270 leaves the bottom plate of the capacitor 230 coupled to VrefP and the bottom plate of the capacitor 230 coupled to VrefN. The SAR 260 may then output a digital signal of 110 to cause the switch control circuit 270 to configure the switches in the switching circuits 224 and 228 to test the bit value of the next bit.

If the compare signal has the first logic value (e.g., one), then the SAR 260 changes the MSB to a bit value of zero. In this case, the switch control circuit 270 causes the switching circuits 224 and 228 to flip the switches for the capacitors 230 and 240 such that the bottom plate of the capacitor 230 is coupled to VrefN and the bottom plate of the capacitor 240 is coupled to VrefP. The SAR 260 may also output a digital signal of 010 to cause the switch control circuit 260 to configure the switches in the switching circuits 224 and 228 to test the bit value of the next bit.

The SAR 260 and the switch control circuit 270 may repeat the above process for each of the remaining bits of the digital signal to resolve the remaining bits. The switch configurations for resolving the remaining bits are known in the art. After all of the bits of the digital signal have been resolved (e.g., three bits in the example shown in FIG. 2), the SAR 260 may output the digital signal with the resolved bits at the output 266. In this example, the digital signal at the output 266 provides a digital representation of the sampled differential signal (e.g., voltage difference between the sampled VinP and sampled VinN).

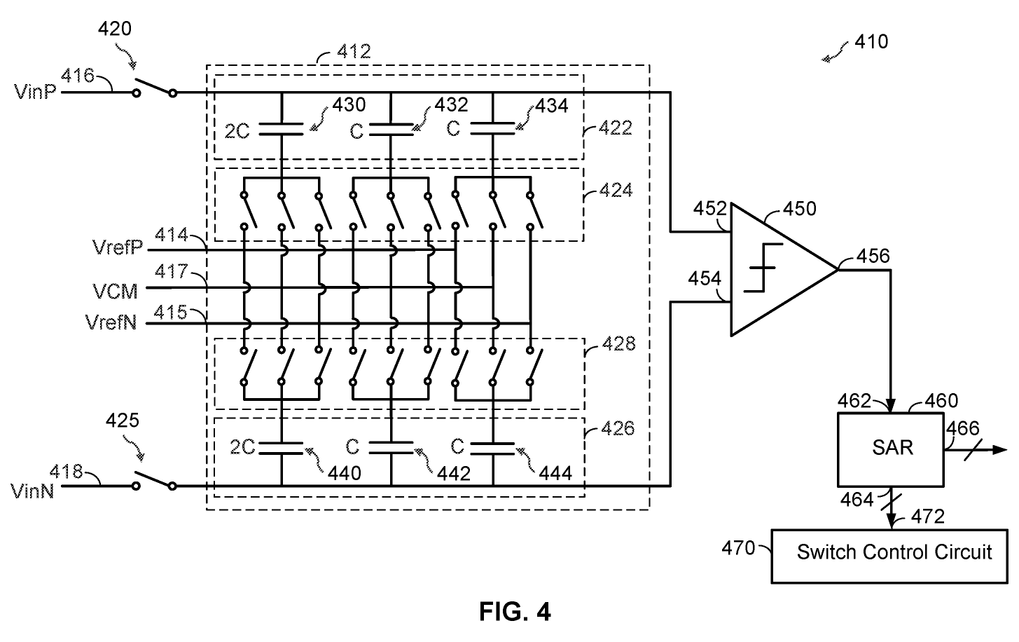

FIG. 4 shows another example of a differential SAR ADC 410 configured to convert a differential analog signal into a digital signal. The differential analog signal includes the first voltage VinP and the second voltage VinN. The SAR ADC 410 includes a capacitive DAC 412, a comparator 450, a SAR 460, a switch control circuit 470, a first switch 420, and a second switch 425. In this example, the SAR ADC 410 uses top plate sampling to sample the differential analog signal instead of the bottom plate sampling used in the SAR ADC 210. The first voltage VinP is received at a first input 416 of the SAR ADC 410 and the second voltage VinN is received at a second input 418 of the SAR ADC 410.

The first input 416 and the second input 418 may be coupled to an output of a device (e.g., the device 125 or the device 175) configured to generate the analog differential signal. The device may include a temperature sensor, a voltage sensor, a current sensor, or another type of device. In some implementations, the first input 416 and the second input 418 may be coupled to the device through one or more drivers (e.g., the drivers 130 or 180) and/or a multiplexer (e.g., the multiplexer 160).

The comparator 450 has a first input 452, a second input 454, and an output 456. The first switch 420 is coupled between the first input 416 of the SAR ADC 410 and the first input 452 of the comparator 450, and the second switch 425 is coupled between the second input 418 of the SAR ADC 410 and the second input 454 of the comparator 450. The comparator 450 is configured to compare the voltage at the first input 452 with the voltage at the second input 454, and output a compare signal at the output 456 based on the comparison. In one example, the compare signal has a first logic value if the voltage at the first input 452 is greater than the voltage at the second input 454, and the compare signal has a second logic value if the voltage at the first input 452 is less than the voltage at the second input 454. The first logic value may be one and the second logic value may be zero, or vice versa.

In the example shown in FIG. 4, the capacitive DAC 412 includes a first capacitor array 422, a second capacitor array 426, a first switching circuit 424, and a second switching circuit 428. The first capacitor array 422 includes a set of capacitors 430, 432, and 434. In this example, the capacitors 430 and 432 are binary-weighted capacitors in which the capacitor 432 has a capacitance of C and the capacitor 430 has a capacitance of 2C. In this example, the SAR ADC 410 has a resolution of three bits without the need for the 4C capacitor for the MSB shown in FIG. 2. This is because the SAR ADC 410 uses top plate sampling in which the MBS decision is made based on the sampled voltages VinP and VinN, which are directly input to the inputs of the comparator 450, as discussed further below. The omission of the 4C capacitor allows for a 2x reduction in the size of the first capacitor array 422 compared with the first capacitor array 222. Each of the capacitors 430, 432 and 434 has a respective top plate coupled to the first input 452 of the comparator 450 and a respective bottom plate coupled to the first switching circuit 424.

The second capacitor array 426 includes a set of capacitors 440, 442, and 444, in which the capacitors 440 and 442 are binary-weighted capacitors. In this example, the capacitor 442 has a capacitance of C and the capacitor 440 has a capacitance of 2C. As discussed above, the 4C capacitor for the MBS may be omitted since the SAR ADC 410 uses top plate sampling, which allows for a 2x reduction in the second capacitor array 426 compared with the second capacitor array 226. Each of the capacitors 440, 442, and 444 has a respective top plate coupled to the second input 454 of the comparator 450 and a respective bottom plate coupled to the second switching circuit 428.

In the example shown in FIG. 4, the capacitive DAC 412 receives the first reference voltage VrefP at a first input 414, receives the second reference voltage VrefN at a second input 415, and receives the common mode voltage VCM at a third input 417. As discussed above, the common mode voltage VCM is between the first reference voltage VrefP and the second reference voltage VrefN.

In this example, the first switching circuit 244 includes switches for selectively coupling the bottom plate of each of the capacitors 430, 432, and 434 in the first capacitor array 422 to VrefP, VCM, or VrefN. The second switching circuit 428 includes switches for selectively coupling the bottom plate of each of the capacitors 440, 442, and 444 in the second capacitor array 426 to VrefP, VCM, or VrefN.

The on/off states of the switches in the switching circuits 424 and 428 are controlled by the switch control circuit 470. For ease of illustration, the individual connections between the switches and the switch control circuit 470 are not shown in FIG. 4. The switch control circuit 470 has an input 472 coupled to the SAR 460. The switch control circuit 470 is configured to receive a digital signal from the SAR 460 at the input 472 and control the switches in the switching circuits 424 and 428 based on the digital signal, as discussed further below.

The switch control circuit 470 may also control the on/off state of the first switch 420 and the second switch 425. The first switch 420 is coupled between the first input 416 (which receives VinP) and the first input 452 of the comparator 450, and the second switch 425 is coupled between the second input 418 (which receives VinN) and the second input 454 of the comparator 450.

The SAR 460 has an input 462, a first output 466, and a second output 464. The input 462 is coupled to the output 456 of the comparator 450 to receive the compare signal. The first output 466 is configured to output the digital signal representing the input differential analog signal (e.g., VinP-VinN) in the digital domain. The second output 464 is configured to output the digital signal to the switch control circuit 470 used to test different bit values during the conversion phase of the SAR ADC 410, as discussed further below.

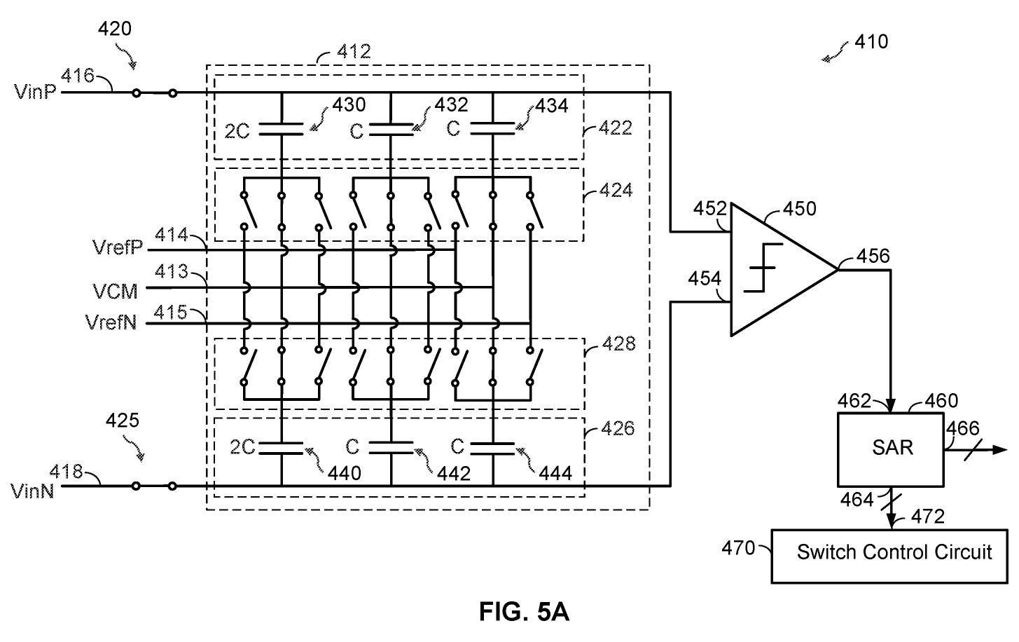

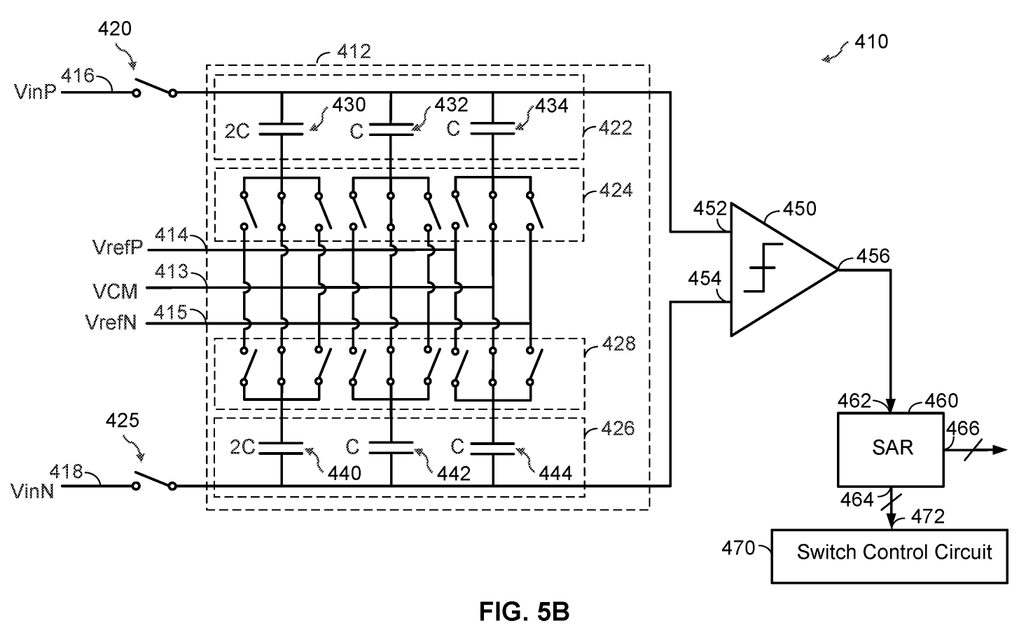

Exemplary operations of the SAR ADC 410 for converting the differential analog signal (e.g., VinP-VinN) into the digital signal at the output 466 will now be described with reference to FIGS. 5A and 5B, which shows the switch configurations of the switching circuits 424 and 428 and the switches 420 and 425 during different phases.

FIG. 5A shows an example of a first phase during which the voltages VinP and Vin of the differential analog signal are sampled. During the first phase, the switch control circuit 270 closes the first switch 420 and the second switch 425. This couples the first voltage VinP to the top plates of the capacitors 430, 432, and 434 and the first input 452 of the comparator 450 and couples the second voltage VinN to the top plates of the capacitors 440, 442, and 444 and the second input 454 of the comparator 450. The switch control circuit 470 also closes the switches between the bottom plates of the capacitors 430, 432, and 434 and the third input 417 and closes the switches between the bottom plates of the capacitors 440, 442, and 444 and the third input 417. As a result, the bottom plates of the capacitors 430, 432, and 434 and the bottom plates of the capacitors 440, 442, and 444 are coupled to the common mode voltage VCM.

FIG. 5B shows an example of a second phase in which the switch control circuit 270 opens the first and second switches 420 and 425 while leaving the bottom plates of the capacitors 430, 432, and 434 and the bottom plates of the capacitors 440, 442, and 444 coupled to the common mode voltage VCM. Since the first voltage VinP is sampled at the top plates of the capacitors 430, 432, and 434 and the second voltage VinN is sampled at the top plates of the capacitors 440, 442, and 444, the sampled voltages VinP and VinN may be input directly to the inputs 452 and 454 of the comparator 250. This reduces the overall conversion time compared with the SAR ADC 210 which requires switching in the switching circuits 224 and 228 to redistribute charge to push the sampled voltages VinP and VinN from the bottom plates of the capacitors in the DAC 212 to the top plates of the capacitors in the DAC 212.

In this example, the comparator 450 compares the sampled voltage VinP at the first input 452 with the sampled voltage VinN at the second input 454 and outputs the compare signal at the output 456 based on the comparison. The SAR 460 may then resolve the MSB based on the compare signal. For example, if the compare signal has the second logic value (e.g., zero), then the SAR 460 may resolve the MSB to the bit value of one. If the compare signal has the first logic value (e.g., one), then the SAR 460 may resolve the MSB to a bit value of zero.

The SAR 460 may then sequentially set the switches in the switching circuits 424 and 428 to different switch configurations to test the bit values of the remaining bits and resolve the bit values of the remaining bits based on the output of the comparator 450. In each switch configuration, the bottom plate of each of the capacitors is coupled to VrefP or VrefN. The switch configuration for testing the bit values of the remaining bits are known in the art. After all of the bits have been resolved (e.g., three bits in the example shown in FIG. 4), the SAR 460 may output the digital signal with the resolved bits at the output 466. In this example, the digital signal at the output 466 provides a digital representation of the sampled differential signal (e.g., voltage difference between the sampled VinP and sampled VinN).

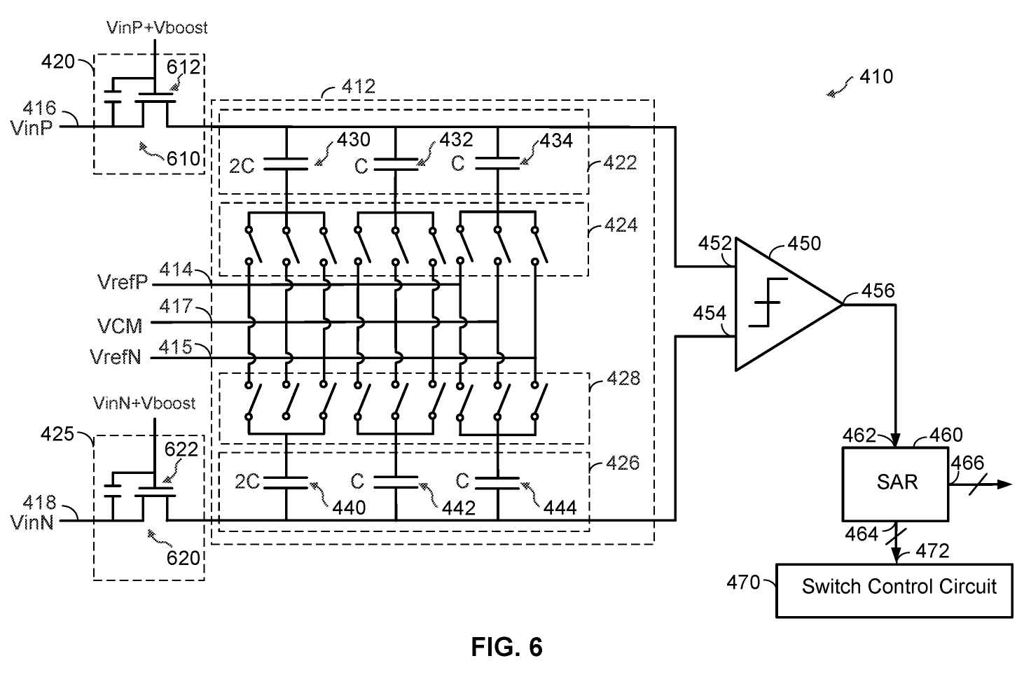

In certain aspects, each of the switches 420 and 425 may be implemented with a respective bootstrap switch to reduce signal dependent on resistance, which reduces nonlinear distortion. As used herein, “on resistance” is the resistance of a switch when the switch is turned on. In this regard, FIG. 6 shows an example in which the first switch 420 includes a first bootstrap switch 610 and the second switch 425 includes a second bootstrap switch 620.

In this example, the first bootstrap switch 610 includes a first switching transistor 612 (e.g., an n-type field effect transistor (NFET)) in which the source of the first switching transistor 612 is coupled to the input 416 and the drain of the first switching transistor 612 is coupled to the top plates of the capacitors 430, 432, and 434.

To turn on the first bootstrap switch 610, the switch control circuit 470 applies a gate voltage of VinP + Vboost to the gate of the first switching transistor 612 where Vboost may be a supply voltage or another voltage. In this example, the switch control circuit 470 is coupled to the source of the first switching transistor 612 in order to sense VinP. For ease of illustration, the connections between the switch control circuit 470 and the first switching transistor 612 are not shown in FIG. 6. The gate voltage of VinP + Vboost causes the gate-to-source voltage VGS of the first switching transistor 612 to be approximately constant at approximately Vboost. This is because the difference between VinP + Vboost at the gate and VinP at the source of the first switching transistor 612 is approximately equal to Vboost. By keeping the gate-to-source voltage VGS approximately constant, the on resistance of the first switching transistor 612 is approximately constant for good linearity.

To turn off the first bootstrap switch 610, the switch control circuit 470 may couple the gate of the first switching transistor 612 to ground. This causes the gate-to-source voltage VGS of the first switching transistor 612 to change from Vboost to -VinP. As discussed further below, this causes signal dependent charge injection when the first switching transistor 612 is opened (i.e., switched off). The charge may come from the gate-to-source capacitance of the first switching transistor 612, which is depicted in FIG. 6 by the capacitor coupled between the gate and the source.

In this example, the second bootstrap switch 620 includes a second switching transistor 622 (e.g., (NFET)) in which the source of the second switching transistor 622 is coupled to the input 418 and the drain of the second switching transistor 622 is coupled to the top plates of the capacitors 440, 442, and 444.

To turn on the second bootstrap switch 620, the switch control circuit 470 applies a gate voltage of VinN + Vboost to the gate of the second switching transistor 622 where Vboost may be a supply voltage or another voltage. In this example, the switch control circuit 470 is coupled to the source of the second switching transistor 622 in order to sense VinN. For ease of illustration, the connections between the switch control circuit 470 and the second switching transistor 622 are not shown in FIG. 6. The gate voltage of VinN + Vboost causes the gate-to-source voltage VGS of the second switching transistor 622 to be approximately constant at approximately Vboost. This is because the difference between VinN + Vboost at the gate and VinN at the source of the second switching transistor 622 is approximately equal to Vboost. By keeping the gate-to-source voltage VGS approximately constant, the on resistance of the second switching transistor 622 is approximately constant for good linearity.

To turn off the second bootstrap switch 620, the switch control circuit 470 may couple the gate of the second switching transistor 622 to ground. This causes the gate-to-source voltage VGS of the second switching transistor 622 to change from Vboost to -VinN. As discussed further below, this causes signal dependent charge injection when the second switching transistor 622 is opened (i.e., switched off). The charge may come from the gate-to-source capacitance of the second switching transistor 622, which is depicted in FIG. 6 by the capacitor coupled between the gate and the source.

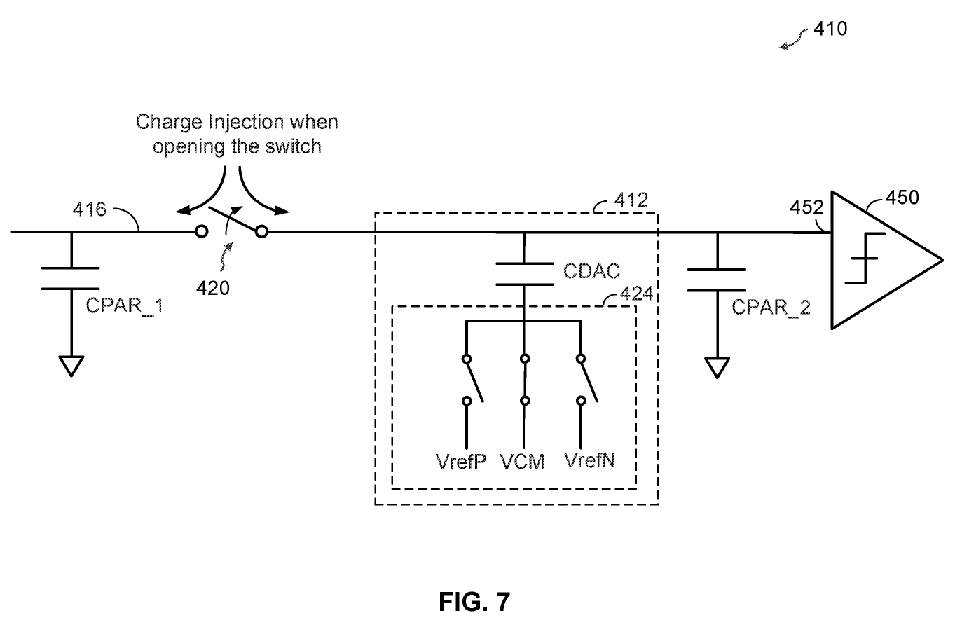

As discussed above, using top plate sampling allows the size of the DAC 412 to be significantly reduced compared with the DAC 212 by omitting the MSB capacitors (e.g., 4C capacitors) in the DAC 212. Top plate sampling also reduces the overall conversion time since charge redistribution is not needed for the MSB decision. However, charge injection from the switches 420 and 425 (which are used as sampling switches) can lead to nonlinear distortion. As example of the charge injection from the first switch 420 is discussed below with reference to FIG. 7. It is to be appreciated that charge injection from the second switch 425 occurs in a similar manner.

FIG. 7 shows an example of the first switch 420, the DAC 412, and the comparator 450. The first switch 420 may be implemented with the bootstrap switch 610 shown in FIG. 6. In FIG. 7, the capacitors 430, 432, and 434 in the first capacitor array 422 are collectively represented by the capacitor CDAC in which the top plate of the capacitor CDAC is coupled between the first switch 420 and the first input 452 of the comparator 450. In FIG. 7, the switches in the first switching circuit 424 are represented by switches for selectively coupling the bottom plate of the capacitor CDAC to VCM, VrefP, or VrefN. The second switch 425, the second capacitor array 426, and the second switching circuit 428 are not shown in FIG. 7 since FIG. 7 illustrates charge injection from the first switch 420. As discussed above, charge injection from the second switch 425 occurs in a similar manner.

FIG. 7 also shows an example of parasitic capacitances on either side of the first switch 420. The parasitic capacitance to the left of the first switch 420 (i.e., on the input side) is represented by the capacitor CPAR_1. This parasitic capacitance may include parasitic capacitances of one or more drivers (e.g., drivers 130 and 180) and/or a multiplexer (e.g., multiplexer 160). The parasitic capacitance to the right of the switch 420 (i.e., on the DAC side) is presented by the capacitor CPAR_2. This parasitic capacitance may include parasitic capacitance from the input 452 of the comparator 450.

In this example, the first switch 420 injects charge into the DAC 412 when opening (i.e., turning off) the first switch 420 in the second phase shown in FIG. 5B. The opening of the first switch 420 is indicated by the arrow on the switch. The opening of the first switch 420 causes the gate-to-source voltage VGS of the first switching transistor 612 (shown in FIG. 6) to change from Vboost to -VinP. The VGS change causes the charge on the capacitor (shown in FIG. 6) of the switching transistor 612 to discharge, which results in the charge injection from the first switch 420.

The charge injection is split between the left side (i.e., input side) and the right side (i.e., DAC side) of the first switch 420, as illustrated by the arrows pointing downward to the left and to the right in FIG. 7. The charge is split based on the impedances on both sides of the first switch 420 at the frequency of interest. The total capacitance (CDAC+CPAR_2) on the DAC side can be much larger than the capacitance (CPAR_1) on the input side. This causes the majority of the charge to be injected into the DAC 412, which increases non-linear distortion. More of the charge injection may be steered to the input side (i.e., away from the DAC 412) by adding decoupling capacitors to the input side. However, the decoupling capacitors may need to be large (and therefore take up a large area) in order to steer most of the charge injection to the input side.

To address the above, aspects of the present disclosure provides a switching sequence for the switches in a capacitive DAC (e.g., the DAC 412) that significantly increases the impedance of the DAC when opening the sampling switches (e.g., the switches 420 and 425). The increased impedance reduces the charge injection into the DAC for better linearity. The above features and other features of the present disclosure are discussed further below.

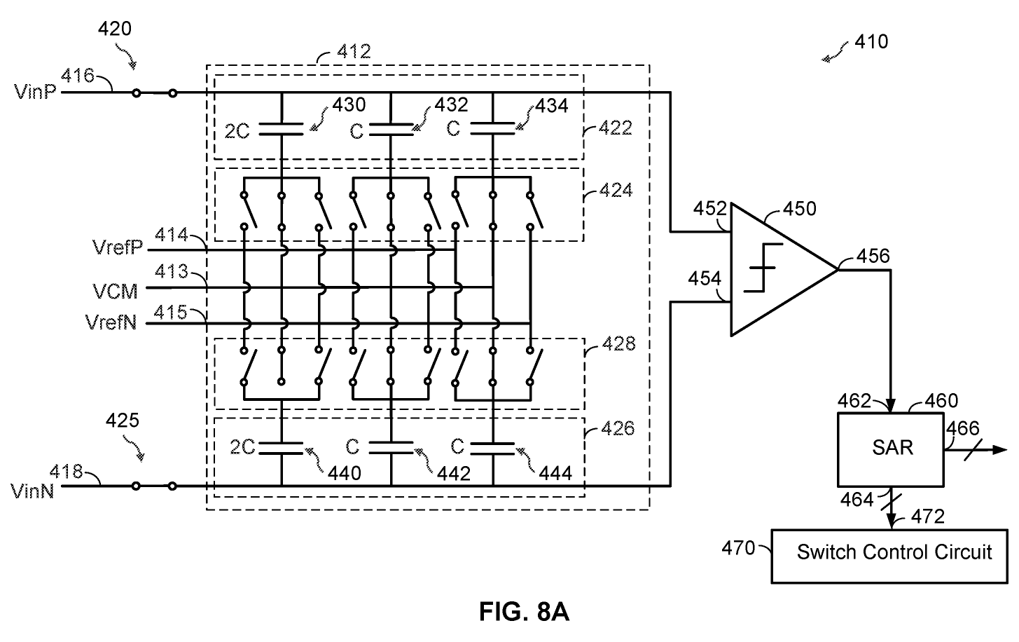

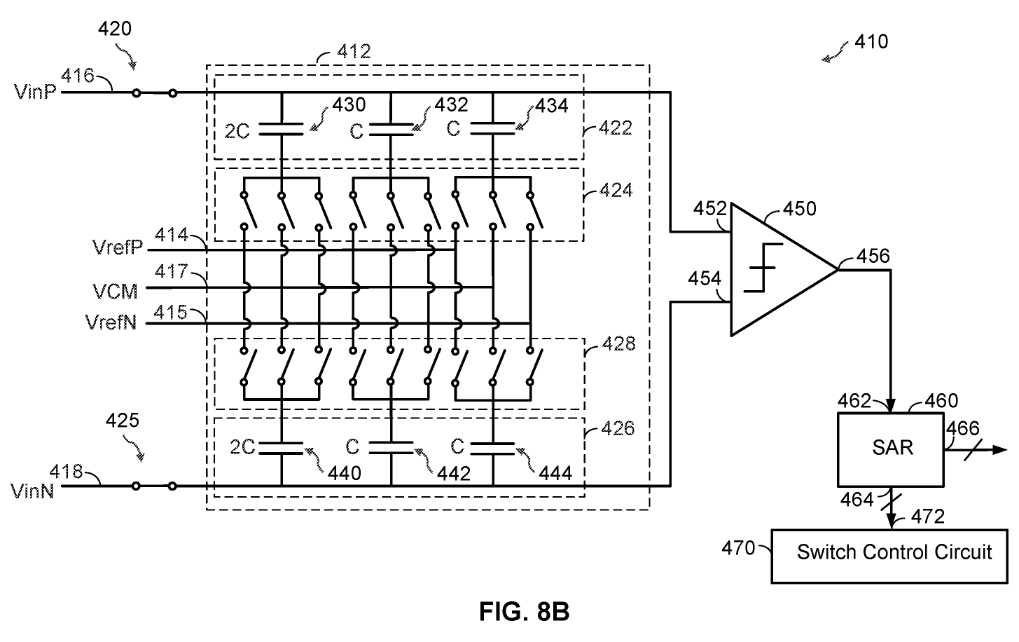

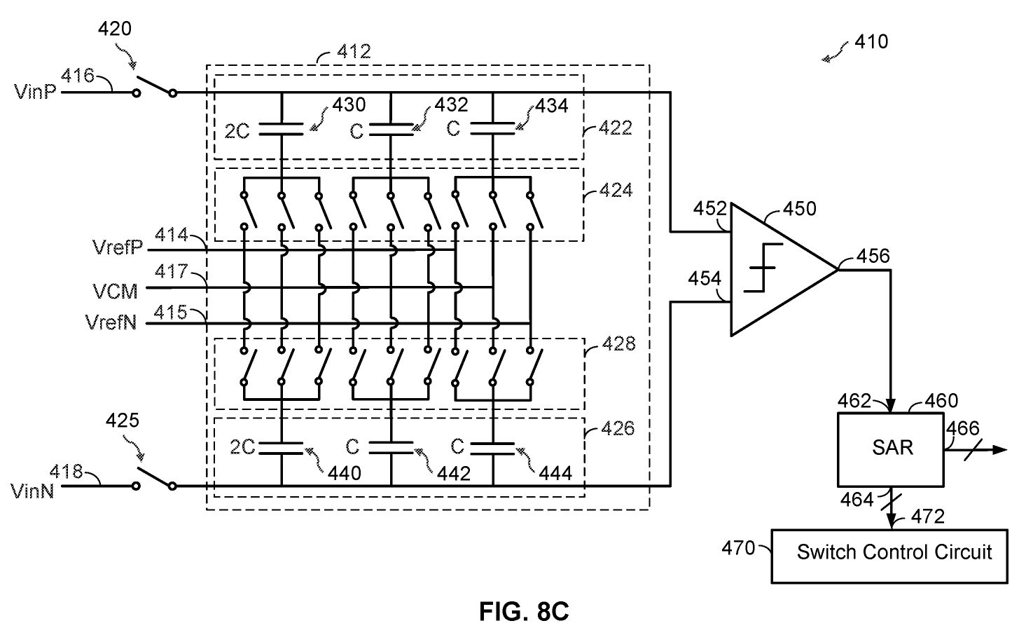

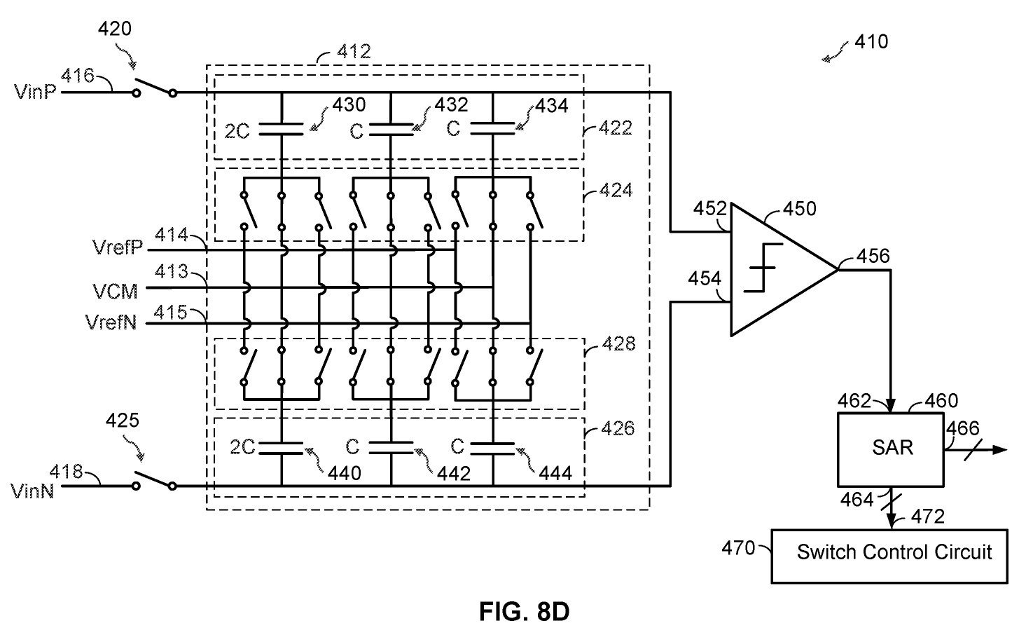

An exemplary switching sequence for reducing charge injection into the DAC 412 is discussed below with reference to FIGS. 8A to 8D.

FIG. 8A shows an example of a first phase in which the switch configuration shown in FIG. 8A is the same as the switch configuration shown in FIG. 5A discussed above. During the first phase, the switch control circuit 470 closes the first switch 420 and the second switch 425. This couples the first voltage VinP to the top plates of the capacitors 430, 432, and 434 and the first input 452 of the comparator 450 and couples the second voltage VinN to the top plates of the capacitors 440, 442, and 444 and the second input 454 of the comparator 450. The switch control circuit 470 also closes the switches between the bottom plates of the capacitors 430, 432, and 434 and the third input 417 and closes the switches between the bottom plates of the capacitors 440, 442, and 444 and the third input 417. As a result, the bottom plates of the capacitors 430, 432, and 434 and the bottom plates of the capacitors 440, 442, and 444 are coupled to the common mode voltage VCM.

FIG. 8B shows an example of a second phase in which the second phase is a new phase for reducing charge injection. During the second phase, the switch control circuit 470 opens the switches between the bottom plates of the capacitors 430, 432, and 434 and the third input 417 and opens the switches between the bottom plates of the capacitors 440, 442, and 444 and the third input 417. As a result, the bottom plates of the capacitors in the DAC 412 are decupled from the common mode voltage VCM. This significantly increases the impedance of the DAC 412. The switches 420 and 425 are left closed, as shown in FIG. 8B.

FIG. 8C shows an example of a third phase in which the third phase is a new phase for reducing charge injection. During the third phase, the switch control circuit 470 opens (i.e., turns off) the switches 420 and 425 (which are used for sampling). The opening of the switches 420 and 425 causes charge injection from the switches 420 and 425. In this example, the impedance of the DAC 412 is high due to the opening of the switches between the bottom plates of the capacitors in the DAC 412 and the common mode voltage VCM in the previous phase (i.e., the second phase). The high impedance of the DAC 412 causes most of the charge injection to flow to the left side (i.e., input side) of the switches 420 and 425 and away from the DAC 412 for better linearity.

FIG. 8D shows an example of a fourth phase in which the switch configuration shown in FIG. 8D is the same as the switch configuration shown in FIG. 5B discussed above. During the fourth phase, the switch control circuit 470 closes the switches between the bottom plates of the capacitors 430, 432, and 434 and the third input 417 and closes the switches between the bottom plates of the capacitors 440, 442, and 444 and the third input 417. As a result, the bottom plates of the capacitors in the DAC 412 are recoupled to the common mode voltage VCM for making the MSB decision, as discussed above with reference to FIG. 5B.

Thus, the exemplary switching sequence illustrated in FIGS. 8A to 8D includes new phases for reducing the charge injection into the DAC 412 for better linearity. The new phases include the second phase illustrated in FIG. 8B during which the switches between the bottom plates of the capacitors in the DAC 412 and the common mode voltage VCM are opened to increase the impedance of the DAC 412. The new phases also includes the third phase illustrated in FIG. 8C during which the switches 420 and 425 (which are used for sampling) are opened while the bottom plates of the capacitors in the DAC 412 are decoupled from the common mode voltage VCM. In this example, the high impedance of the DAC 412 steers most of the charge injection to left side (i.e., input side) of the switches 420 and 425, thereby reducing charge injection into the DAC 412.

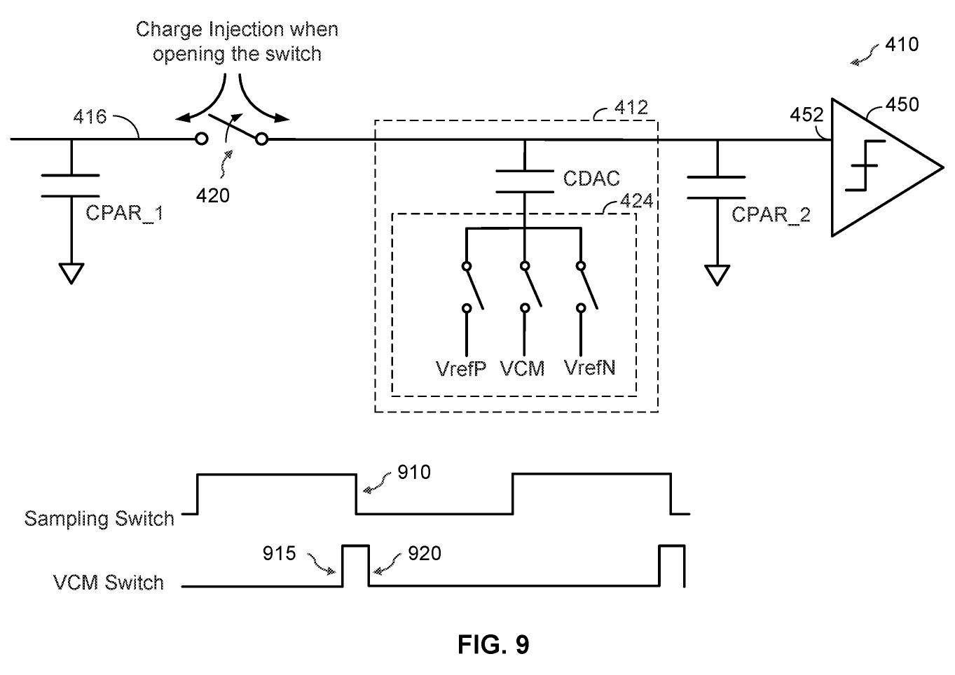

An example of the reduction of charge injection from the first switch 420 is illustrated in FIG. 9. It is to be appreciated that the charge injection from the second switch 425 is reduced in a similar manner.

In this example, the first switch 420 injects charge into the DAC 412 when opening (i.e., turning off) the first switch 420 in the third phase shown in FIG. 8C. The opening of the first switch 420 is indicated by the arrow on the switch. As shown in FIG. 9, when the first switch 420 is opened, the bottom plate of the capacitor CDAC (which collectively represents the capacitors 430, 432, and 434) is decoupled from the common mode voltage VCM. This causes the impedance of the DAC 412 to be high when the first switch 420 is opened.

The opening of the first switch 420 causes the gate-to-source voltage VGS of the first switching transistor 612 (shown in FIG. 6) to change from Vboost to -VinP. The VGS change causes the charge on the capacitor (shown in FIG. 6) of the switching transistor 612 to discharge, which results in the charge injection from the first switch 420. The charge injection is split between the left side (i.e., input side) and the right side (i.e., DAC side) of the first switch 420, as illustrated by the arrows pointing downward to the left and to the right in FIG. 9. In this example, the high impedance of the DAC 412 causes most of the charge injection to be steered to the left side. As a result, the charge injection into the DAC 412 is reduced for better linearity.

FIG. 9 also shows an example of timing signals that may be used by the switch control circuit 470 for timing the switching of the first switch 420 and the VCM switch. The VCM switch includes the switches coupled between the bottom plates of the capacitors 430, 432, and 434 (shown in FIG. 4) and VCM.

In the example in FIG. 9, the timing signals include a first timing signal (labeled “sampling switch”) for controlling the timing of the first switch 420 and a second timing signal (labeled “VCM switch”) for controlling the timing of the VCM switch. In this example, the switch control circuit 470 turns on the first switch 420 when the first timing signal is high and turns off the first switch 420 when the first timing signal is low. Also, the switch control circuit 470 turns on the VCM switch when the second timing signal is low and turns off the VCM switch when the second timing signal is high.

In the example in FIG. 9, the switch control circuit 470 opens the first switch 420 on the falling edge 910 of the first timing signal. The switch control circuit 470 also opens the VCM switch on the rising edge 915 of the second timing signal and closes the VCM switch on the falling edge 920 of the second timing signal. As shown in FIG. 9, the VCM switch is opened before the first switch 420 is opened to increase the impedance of the DAC 412 before the first switch 420 is opened. After the first switch 420 is opened, the VCM switch is closed for the MSB decision.

It is to be appreciated that charge injection reduction according to aspects of the present disclosure are not limited to differential SAR ADCs. For example, aspects of the present disclosure may be used to reduce charge injection into a capacitive DAC in a single-ended SAR ADC. In this example, the single-ended SAR ADC may include the first switch 420, the first capacitor array 422, the first switching circuit 424, the comparator 450, the SAR 460, and the switch control circuit 470 with the second switch 425, the second capacitor array 426, and the second switching circuit 428 omitted. In this example, the second input 454 of the comparator 450 may be coupled to ground or another voltage. Also, the first switching circuit 424 may be configured to selectively couple the bottom plate of each of the capacitors 430, 432, and 434 to ground (or the other voltage) or a reference voltage Vref. In this example, the charge injection from the first switch 420 may be reduced using the exemplary switching sequence illustrated in FIGS. 8A and 8D with the common mode voltage VCM replaced with the ground or the other voltage.

It is to be appreciated that coupling the bottom plates of the capacitors 430, 432, and 434 to a common mode voltage VCM may also be achieved by splitting each of the capacitors 430, 432, and 434 into two capacitors in which one of the capacitors is coupled to VrefP and the other one of the capacitors is coupled to VrefN. In this case, the common mode voltage VCM is the average of VrefP and VrefN.

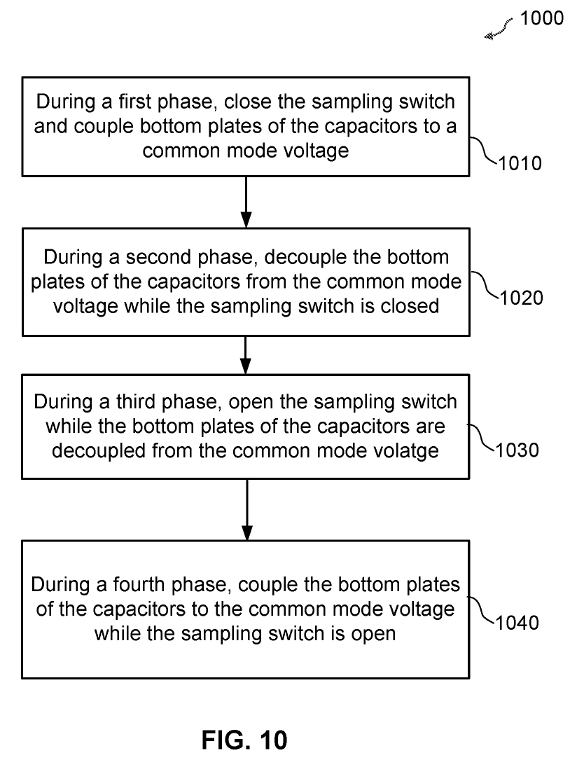

FIG. 10 illustrates an exemplary method 1000 for operating an analog-to-digital converter (ADC) according to certain aspects. The ADC (e.g., the SAR ADC 410) includes a comparator (e.g., the comparator 450), a sampling switch (e.g., the first switch 420) coupled between a device (e.g., the device 125 or 175) outputting an analog voltage and an input (the first input 452) of the comparator, and a capacitor array (e.g., the first capacitor array 422) including capacitors, wherein top plates of the capacitors are coupled between the sampling switch and the input of the comparator. The device may include a temperature sensor, a voltage sensor, or a current sensor.

At block 1010, during a first phase, the sampling switch is closed and the bottom plates of the capacitors are coupled to a common mode voltage. For example, the sampling switch may be closed by the switch control circuit 470 and bottom plates of the capacitors may be coupled to the common mode voltage by the switching circuit 424.

At block 1020, during a second phase, the bottom plates of the capacitors are decoupled from the common mode voltage while the sampling switch is closed. For example, the bottom plates of the capacitors may be decoupled from the common mode voltage by the switching circuit 424.

At block 1030, during a third phase, the sampling switch is opened while the bottom plates of the capacitors are decoupled from the common mode voltage. For example, the sampling switch may be opened by the switch control circuit 470.

At block 1040, during a fourth phase, the bottom plates of capacitors are coupled to the common mode voltage while the sampling switch is open. For example, the bottom plates of the capacitors may be coupled to the common mode voltage by the switching circuit 424.

The method 1000 may also include, during the fourth phase, making a bit decision based on an output of the comparator. For example, the bit decision may be made by the SAR 460. The bit decision may be for a most significant bit (MSB).

The method 1000 may also include, after the fourth phase, receiving a digital signal, and coupling each of the bottom plates of the capacitors to a first reference voltage or a second reference voltage based on the digital signal. For example, the switch control circuit 470 may receive the digital signal from the SAR 460 during the conversion phase, and couple the each of the bottom plates of the capacitors to the first reference voltage (e.g., VrefP) or the second reference voltage (e.g., VrefN) based on the digital signal. In certain aspects, the most significant bit of the digital signal is set based on the bit decision made during the fourth phase.

Implementation examples are described in the following numbered clauses:

1. An analog-to-digital converter (ADC), comprising:

a comparator;

a first sampling switch coupled to a first input of the comparator;

a capacitive digital-to-analog convert (DAC), the capacitive DAC comprising:

a first capacitor array comprising first capacitors, wherein top plates of the first capacitors are coupled between the first sampling switch and the first input of the comparator; and

a first switching circuit configured to selectively couple bottom plates of the first capacitors to a common mode voltage;

a switch control circuit configured to:

during a first phase, close the first sampling switch and cause the first switching circuit to couple the bottom plates of the first capacitors to the common mode voltage;

during a second phase, cause the first switching circuit to decouple the bottom plates of the first capacitors from the common mode voltage while the first sampling switch is closed;

during a third phase, open the first sampling switch while the bottom plates of the first capacitors are decoupled from the common mode voltage; and

during a fourth phase, cause the first switching circuit to couple the bottom plates of first capacitors to the common mode voltage while the first sampling switch is open; and

a successive approximation register (SAR) coupled to an output of the comparator, wherein, during the fourth phase, the SAR is configured to make a bit decision based on the output of the comparator.

2. The ADC of clause 1, wherein the bit decision is for a most significant bit (MSB).

3. The ADC of clause 1 or 2, wherein the first switching circuit is also configured to selectively couple each of the bottom plates of the first capacitors to a first reference voltage and selectively couple each of the bottom plates of the first capacitors to a second reference voltage.

4. The ADC of clause 3, wherein the common mode voltage is equal to an average of the first reference voltage and the second reference voltage.

5. The ADC of clause 3 or 4, wherein the SAR is configured to output a digital signal to the first switching circuit, and, after the fourth phase, the first switching circuit is configured to selectively couple each of the bottom plates of the first capacitors to the first reference voltage or the second reference voltage based on the digital signal.

6. The ADC of clause 5, wherein the SAR is configured to set a most significant bit (MSB) of the digital signal based on the bit decision made during the fourth phase.

7. The ADC of any one of clauses 1 to 6, wherein the first sampling switch is coupled between an output of a device and the first input of the comparator, and the device is configured to output an analog voltage at the output of the device.

8. The ADC of clause 7, wherein the device comprises a temperature sensor, a voltage sensor, or a current sensor.

9. The ADC of any one of clauses 1 to 8, further comprising a second sampling switch coupled to a second input of the comparator.

10. The ADC of clause 9, wherein:

the capacitive DAC further comprises:

a second capacitor array comprising second capacitors, wherein top plates of the second capacitors are coupled between the second sampling switch and the second input of the comparator; and

a second switching circuit configured to selectively couple bottom plates of the second capacitors to the common mode voltage; and

the switch control circuit is configured to:

during the first phase, close the second sampling switch and cause the second switching circuit to couple the bottom plates of the second capacitors to the common mode voltage;

during the second phase, cause the second switching circuit to decouple the bottom plates of the second capacitors from the common mode voltage while the second sampling switch is closed;

during the third phase, open the second sampling switch while the bottom plates of the second capacitors are decoupled from the common mode voltage; and

during a fourth phase, cause the second switching circuit to couple the bottom plates of the second capacitors to the common mode voltage while the second sampling switch is open.

11. A method for operating an analog-to-digital converter (ADC), the ADC including a comparator, a sampling switch coupled between a device outputting an analog voltage and an input of the comparator, and a capacitor array including capacitors, wherein top plates of the capacitors are coupled between the sampling switch and the input of the comparator, the method comprising:

during a first phase, closing the sampling switch and coupling bottom plates of the capacitors to a common mode voltage;

during a second phase, decoupling the bottom plates of the capacitors from the common mode voltage while the sampling switch is closed;

during a third phase, opening the sampling switch while the bottom plates of the capacitors are decoupled from the common mode voltage; and

during a fourth phase, coupling the bottom plates of capacitors to the common mode voltage while the sampling switch is open.

12. The method of clause 11, further comprising, during the fourth phase, making a bit decision based on an output of the comparator.

13. The method of clause 12, wherein the bit decision is for a most significant bit (MSB).

14. The method of clause 12 or 13, further comprising, after the fourth phase, receiving a digital signal, and coupling each of the bottom plates of the capacitors to a first reference voltage or a second reference voltage based on the digital signal.

15. The method of clause 14, further comprising setting a most significant bit of the digital signal based on the bit decision made during the fourth phase.

16. The method of clause 14 or 15, wherein the common mode voltage is equal to an average of the first reference voltage and the second reference voltage.

17. The method of any one of clauses 11 to 16, wherein the device comprises a temperature sensor, a voltage sensor, or a current sensor.

The SAR 460 and/or the switch control circuit 470 may be implemented with a general-purpose processor, a digital signal processor (DSP), an application specific integrated circuit (ASIC), a field programmable gate array (FPGA) or other programmable logic device, a digital finite state machine (FSM), discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An analog-to-digital converter (ADC), comprising:
a comparator;
a first sampling switch coupled to a first input of the comparator;
a capacitive digital-to-analog convert (DAC), the capacitive DAC comprising:
a first capacitor array comprising first capacitors, wherein top plates of the first capacitors are coupled between the first sampling switch and the first input of the comparator; and
a first switching circuit configured to selectively couple bottom plates of the first capacitors to a common mode voltage;
a switch control circuit configured to:
during a first phase, close the first sampling switch and cause the first switching circuit to couple the bottom plates of the first capacitors to the common mode voltage;
during a second phase, cause the first switching circuit to decouple the bottom plates of the first capacitors from the common mode voltage while the first sampling switch is closed;
during a third phase, open the first sampling switch while the bottom plates of the first capacitors are decoupled from the common mode voltage; and
during a fourth phase, cause the first switching circuit to couple the bottom plates of first capacitors to the common mode voltage while the first sampling switch is open; and
a successive approximation register (SAR) coupled to an output of the comparator, wherein, during the fourth phase, the SAR is configured to make a bit decision based on the output of the comparator.

2. The ADC of claim 1, wherein the bit decision is for a most significant bit (MSB).

3. The ADC of claim 1, wherein the first switching circuit is also configured to selectively couple each of the bottom plates of the first capacitors to a first reference voltage and selectively couple each of the bottom plates of the first capacitors to a second reference voltage.

4. The ADC of claim 3, wherein the common mode voltage is equal to an average of the first reference voltage and the second reference voltage.

5. The ADC of claim 3, wherein the SAR is configured to output a digital signal to the first switching circuit, and, after the fourth phase, the first switching circuit is configured to selectively couple each of the bottom plates of the first capacitors to the first reference voltage or the second reference voltage based on the digital signal.

6. The ADC of claim 5, wherein the SAR is configured to set a most significant bit (MSB) of the digital signal based on the bit decision made during the fourth phase.

7. The ADC of claim 1, wherein the first sampling switch is coupled between an output of a device and the first input of the comparator, and the device is configured to output an analog voltage at the output of the device.

8. The ADC of claim 7, wherein the device comprises a temperature sensor, a voltage sensor, or a current sensor.

9. The ADC of claim 1, further comprising a second sampling switch coupled to a second input of the comparator.

10. The ADC of claim 9, wherein:
the capacitive DAC further comprises:
a second capacitor array comprising second capacitors, wherein top plates of the second capacitors are coupled between the second sampling switch and the second input of the comparator; and
a second switching circuit configured to selectively couple bottom plates of the second capacitors to the common mode voltage; and
the switch control circuit is configured to:
during the first phase, close the second sampling switch and cause the second switching circuit to couple the bottom plates of the second capacitors to the common mode voltage;
during the second phase, cause the second switching circuit to decouple the bottom plates of the second capacitors from the common mode voltage while the second sampling switch is closed;
during the third phase, open the second sampling switch while the bottom plates of the second capacitors are decoupled from the common mode voltage; and
during a fourth phase, cause the second switching circuit to couple the bottom plates of the second capacitors to the common mode voltage while the second sampling switch is open.

11. A method for operating an analog-to-digital converter (ADC), the ADC including a comparator, a sampling switch coupled between a device outputting an analog voltage and an input of the comparator, and a capacitor array including capacitors, wherein top plates of the capacitors are coupled between the sampling switch and the input of the comparator, the method comprising:
during a first phase, closing the sampling switch and coupling bottom plates of the capacitors to a common mode voltage;
during a second phase, decoupling the bottom plates of the capacitors from the common mode voltage while the sampling switch is closed;
during a third phase, opening the sampling switch while the bottom plates of the capacitors are decoupled from the common mode voltage; and
during a fourth phase, coupling the bottom plates of capacitors to the common mode voltage while the sampling switch is open.

12. The method of claim 11, further comprising, during the fourth phase, making a bit decision based on an output of the comparator.

13. The method of claim 12, wherein the bit decision is for a most significant bit (MSB).

14. The method of claim 12, further comprising, after the fourth phase, receiving a digital signal, and coupling each of the bottom plates of the capacitors to a first reference voltage or a second reference voltage based on the digital signal.

15. The method of claim 14, further comprising setting a most significant bit of the digital signal based on the bit decision made during the fourth phase.

16. The method of claim 14, wherein the common mode voltage is equal to an average of the first reference voltage and the second reference voltage.

17. The method of claim 11, wherein the device comprises a temperature sensor, a voltage sensor, or a current sensor.
